(19) United States
(12) Patent Application Publication
(10) Pub. No.: US 2025/0056772 A1
(43) Pub. Date: Feb. 13, 2025

(54) INTELLIGENT TEMPERATURE CONTROL AND BALANCE OF DATACENTER LIQUID COOLING ARRANGEMENTS

(71) Applicant: OVH, Roubaix (FR)

(72) Inventor: Ali CHEHADE, Moncheaux (FR)

(21) Appl. No.: 18/792,322

(22) Filed: Aug. 1, 2024

(30) Foreign Application Priority Data
Aug. 7, 2023 (EP) 23306347.8

(51) Int. Cl. H05K 7/20; G05D 23/19

(52) U.S. Cl. CPC H05K 7/20836; G05D 23/1917; H05K 7/20272; H05K 7/20781

(57) ABSTRACT

A liquid cooling method and system for cooling rack-mounted processing assemblies is presented that provides a dry cooling unit, a first liquid distribution circuit to convey the cooling liquid and a second liquid distribution circuit to convey the heated liquid from the rack-mounted processing assemblies, in which each of the rack-mounted data processing assemblies comprises a smart control valve designed to be pressure independent and control the flow rate of the cooling fluid based on detected temperatures and pressure flows. Each of the smart control valves operative to measure current liquid flow rates, current input cooling liquid temperatures, and current output heated liquid temperatures and calculate a current differential temperature, determine a relationship between the current differential temperature and a target temperature value, and dynamically adjust the liquid flow rate of the smart control valve based on the determined relationship and the current liquid flow rate and current input cooling liquid temperature.

### CROSS REFERENCE

The present application claims priority to EP Application No EP 23306347.8 filed Aug. 7, 2023, entitled “INTELLIGENT TEMPERATURE CONTROL AND BALANCE OF DATACENTER LIQUID COOLING ARRANGEMENTS”, the entirety of which is incorporated herein by reference.

### FIELD

The present technology generally relates to the field of datacenter cooling measures and, in particular, to the control and balance of liquid cooling arrangements for datacenter rack-mounted processing assemblies.

### BACKGROUND

Datacenters as well as many computer processing facilities house multitudes rack-mounted electronic processing equipment. In operation, such electronic processing equipment generates a substantial amount of heat that must be dissipated in order avoid electronic component failures and ensure continued efficient processing operations.

To this end, various liquid cooling measures have been implemented to facilitate the dissipation of heat generated by the electronic processing equipment. One such measure employs liquid block cooling techniques for directly cooling one or more heat-generating processing components. This technique utilizes liquid cooling blocks having internal channels that receive cooling liquid from a cooling liquid source, e.g., heat exchangers, dry coolers, municipal water supply etc., via a liquid cooling loop arrangement to circulate the cooling liquid throughout the equipment. As such, the liquid cooling blocks are positioned to be in direct thermal contact with the heat-generating components, so that the received cooling liquid absorbs the generated heat and the heated liquid is circulated, via the cooling loop arrangement, back to cooling liquid source for re-cooling.

Another liquid cooling measure employs liquid immersive cooling (IC) techniques, in which the electronic processing equipment is disposed within an immersion case containing cooling dielectric fluid. In this manner, the submerged electronic processing equipment radiates heat that is absorbed by the cooling dielectric fluid in which the heated dielectric fluid is circulated, via a cooling loop arrangement, back to cooling source for re-cooling.

Relatedly, hybrid liquid cooling measures have been introduced that employ a combination of both liquid block cooling techniques and liquid IC techniques as well as various cooling loop arrangements in efforts to maximize the cooling of electronic processing equipment.

With this said, there remains an interest in improving the control and balance of cooling liquid temperatures received by the electronic processing equipment and heated liquid temperatures returned back to cooling sources to optimize cooling efficiency.

The subject matter discussed in the background section should not be assumed to be prior art merely as a result of its mention in the background section. Similarly, a problem mentioned in the background section or associated with the subject matter of the background section should not be assumed to have been previously recognized in the prior art. The subject matter in the background section merely represents different approaches.

### SUMMARY

Embodiments of the present technology have been developed based on certain drawbacks associated with conventional dry cooling techniques and implementations.

In one aspect, the inventive concepts of the present technology provides a method for controlling and balancing a liquid cooling arrangement for datacenter rack-mounted processing assemblies comprising providing a dry cooling unit to supply a cooling liquid to the rack-mounted processing assemblies and receive a heated liquid from the rack-mounted processing assemblies; providing a first liquid distribution circuit to convey the cooling liquid from the dry cooling unit to the rack-mounted processing assemblies and a second liquid distribution circuit to convey the heated liquid from the rack-mounted processing assemblies to the dry cooling unit in which each of the rack-mounted data processing assemblies comprises: at least one heat-generating electronic processing element and at least one liquid cooling block arranged to be in respective thermal contact with the at least one heat-generating electronic processing element, the at least one liquid cooling block being fluidly-coupled to the first liquid distribution circuit to receive the cooling liquid and circulate therethrough, and a smart control valve respectively arranged to be fluidly-coupled to the at least one liquid cooling block of the corresponding rack-mounted data processing assembly, the smart control valve is configured to be pressure independent and controls the flow rate of the cooling fluid of the corresponding rack-mounted data processing assembly based on detected temperatures and pressure flows.

The method also comprises that each smart control valve operates to execute an initialization process including measuring the liquid flow rate, input cooling liquid temperature, and output heated liquid temperature of the corresponding rack-mounted data processing assembly, and calculating a differential temperature between the input cooling liquid temperature and output heated liquid temperature, determining a relationship between the differential temperature and a target temperature value, and initializing the liquid flow rate of the smart control valve based on the determined relationship prior to operations.

The method also comprises that each smart control valve operates to execute an operational process comprising measuring a current liquid flow rate, current input cooling liquid temperature, and current output heated liquid temperature of the corresponding rack-mounted data processing assembly, and calculating a current differential temperature between the current input cooling liquid temperature and current output heated liquid temperature, determining a relationship between the current differential temperature and a target temperature value, and dynamically adjusting the liquid flow rate of the smart control valve based on the determined relationship and the current liquid flow rate and current input cooling liquid temperature.

The method further comprises that for the initialization process, when the differential temperature is less than the target temperature value, decrementing the liquid flow rate of the corresponding smart control valve after confirming that the decremented flow rate is not below a minimum flow rate limit, when the differential temperature is equal to the target temperature value, determining whether at the input cooling liquid temperature, internal temperatures of the rack-mounted processing assembly are less than a predetermined lower temperature limit, when the internal temperatures are less than the predetermined lower temperature limit, decrementing the liquid flow rate of the corresponding smart control valve, and when the internal temperatures are greater than the predetermined lower temperature limit, incrementing the liquid flow rate of the corresponding smart control valve.

The method further comprises that for the operational process, when the current differential temperature is greater than the target temperature value, incrementing the liquid flow rate of the corresponding smart control valve, when the incremented liquid flow rate is the same as the current flow rate, issuing an alert message indicating that the liquid flow rate of the corresponding smart control valve is insufficient, when the current differential temperature is less than the target temperature value, decrementing the liquid flow rate of the corresponding smart control valve after confirming that the decremented flow rate is not below a minimum flow rate limit.

The method additionally comprises that for the operational process, when the current differential temperature is equal to the target temperature value, determining whether at the current input cooling liquid temperature, internal temperatures of the rack-mounted processing assembly are less than a predetermined lower temperature limit, when the internal temperatures are less than the predetermined lower temperature limit, decrementing the liquid flow rate of the corresponding smart control valve, and then checking whether the decremented flow rate is below a minimum flow rate limit or the current differential temperature is greater than the target temperature plus an offset temperature.

The method also comprises that for the operational process, when the decremented flow rate is below a minimum flow rate limit or the current differential temperature is greater than the target temperature plus an offset temperature, incrementing the current liquid flow rate of the corresponding smart control valve, when the internal temperatures of the rack-mounted processing assembly are greater than a predetermined lower temperature limit, issuing a message indicating a precautionary message indicating a potential trend of high temperatures and incrementing the incrementing the current liquid flow rate of the corresponding smart control valve.

In a related aspect of the inventive concepts, the present technology provides a controlled and balanced liquid cooling arrangement for datacenter rack-mounted processing assemblies, comprising a dry cooling unit configured to supply a cooling liquid to the rack-mounted processing assemblies and receive a heated liquid from the rack-mounted processing assemblies; a first liquid distribution circuit configured to convey the cooling liquid from the dry cooling unit to the rack-mounted processing assemblies, the first liquid distribution circuit incorporating a pump configured to drive a flow of the cooling liquid supplied by the dry cooling unit; a second liquid distribution circuit configured to convey the heated liquid from the rack-mounted processing assemblies to the dry cooling unit; in which each of the rack-mounted data processing assemblies comprises: at least one heat-generating electronic processing element, at least one liquid cooling block arranged to be in respective thermal contact with the at least one heat-generating electronic processing element, the at least one liquid cooling block being fluidly-coupled to the first liquid distribution circuit to receive the cooling liquid and circulate therethrough, and a smart control valve respectively arranged to be fluidly-coupled to the at least one liquid cooling block of the corresponding rack-mounted data processing assembly, the smart control valve is configured to be pressure independent and controls the flow rate of the cooling fluid of the corresponding rack-mounted data processing assembly based on detected temperatures and pressure flows.

The liquid cooling arrangement also comprises that each smart control valve operates in an initialization mode to measure the liquid flow rate, input cooling liquid temperature, and output heated liquid temperature of the corresponding rack-mounted data processing assembly, calculate a differential temperature between the input cooling liquid temperature and output heated liquid temperature, determine a relationship between the differential temperature and a target temperature value, and initialize the liquid flow rate of the smart control valve based on the determined relationship prior to an operational mode.

The liquid cooling arrangement further comprises that each smart control valve operates in an operational mode in which when the current differential temperature is greater than the target temperature value, incrementing the liquid flow rate of the corresponding smart control valve and if the incremented liquid flow rate is the same as the current flow rate, issuing an alert message indicating that the liquid flow rate of the corresponding smart control valve is insufficient; when the current differential temperature is equal to the target temperature value, determining whether at the current input cooling liquid temperature, internal temperatures of the rack-mounted processing assembly are less than a predetermined lower temperature limit; and when the internal temperatures are less than the predetermined lower temperature limit, decrementing the liquid flow rate of the corresponding smart control valve, and then checking whether the decremented flow rate is below a minimum flow rate limit or the current differential temperature is greater than the target temperature plus an offset temperature.

The liquid cooling arrangement additionally comprises that when in operational mode, for the current input cooling liquid temperature, when the internal temperatures of the rack-mounted processing assembly are greater than a predetermined lower temperature limit, issuing a message indicating a precautionary message indicating a potential trend of high temperatures and incrementing the incrementing the current liquid flow rate of the corresponding smart control valve.

In the context of the present specification, unless expressly provided otherwise, a computer system may refer, but is not limited to, an “electronic device”, an “operation system”, a “system”, a “computer-based system”, a “controller unit”, a “monitoring device”, a “control device” and/or any combination thereof appropriate to the relevant task at hand.

In the context of the present specification, unless expressly provided otherwise, the expression “computer-readable medium” and “memory” are intended to include media of any nature and kind whatsoever, non-limiting examples of which include RAM, ROM, disks (CD-ROMs, DVDs, floppy disks, hard disk drives, etc.), USB keys, flash memory cards, solid state-drives, and tape drives. Still in the context of the present specification, “a” computer-readable medium and “the” computer-readable medium should not be construed as being the same computer-readable medium. To the contrary, and whenever appropriate, “a” computer-readable medium and “the” computer-readable medium may also be construed as a first computer-readable medium and a second computer-readable medium.

In the context of the present specification, unless expressly provided otherwise, the words “first”, “second”, “third”, etc. have been used as adjectives only for the purpose of allowing for distinction between the nouns that they modify from one another, and not for the purpose of describing any particular relationship between those nouns.

Implementations of the present technology each have at least one of the above-mentioned object and/or aspects, but do not necessarily have all of them. It should be understood that some aspects of the present technology that have resulted from attempting to attain the above-mentioned object may not satisfy this object and/or may satisfy other objects not specifically recited herein.

Additional and/or alternative features, aspects and advantages of implementations of the present technology will become apparent from the following description, the accompanying drawings and the appended claims.

### BRIEF DESCRIPTION OF THE DRAWINGS

For a better understanding of the present technology, as well as other aspects and further features thereof, reference is made to the following description which is to be used in conjunction with the accompanying drawings, where:

FIG. 1 illustrates a high-level functional block diagram of a controlled and balanced liquid cooling arrangement for datacenter rack-mounted processing assemblies, in accordance with the nonlimiting embodiments of the present technology;

FIG. 2A illustrates a flow diagram of a initialization process for controlling and balancing a liquid cooling system for rack-mounted processing assemblies, in accordance with the nonlimiting embodiments of the present technology; and

FIG. 2B illustrates a flow diagram of an operational continuous process for controlling and balancing a liquid cooling system for rack-mounted processing assemblies, in accordance with the nonlimiting embodiments of the present technology.

It should be appreciated that, unless otherwise explicitly specified herein, the drawings are not to scale.

### DETAILED DESCRIPTION

The examples and conditional language recited herein are principally intended to aid the reader in understanding the principles of the present technology and not to limit its scope to such specifically recited examples and conditions. It will be appreciated that those skilled in the art may devise various arrangements that, although not explicitly described or shown herein, nonetheless embody the principles of the present technology.

Furthermore, as an aid to understanding, the following description may describe relatively simplified implementations of the present technology. As persons skilled in the art would understand, various implementations of the present technology may be of a greater complexity.

In some cases, what are believed to be helpful examples of modifications to the present technology may also be set forth. This is done merely as an aid to understanding, and, again, not to define the scope or set forth the bounds of the present technology. These modifications are not an exhaustive list, and a person skilled in the art may make other modifications while nonetheless remaining within the scope of the present technology. Further, where no examples of modifications have been set forth, it should not be interpreted that no modifications are possible and/or that what is described is the sole manner of implementing that element of the present technology.

Moreover, all statements herein reciting principles, aspects, and implementations of the present technology, as well as specific examples thereof, are intended to encompass both structural and functional equivalents thereof, whether they are currently known or developed in the future. Thus, for example, it will be appreciated by those skilled in the art that any block diagrams herein represent conceptual views of illustrative circuitry embodying the principles of the present technology. Similarly, it will be appreciated that any flowcharts, flow diagrams, state transition diagrams, pseudo-code, and the like represent various processes that may be substantially represented in non-transitory computer-readable media and so executed by a computer or processor, whether or not such computer or processor is explicitly shown.

The functions of the various elements shown in the FIGs. including any functional block labeled as a “processor”, may be provided through the use of dedicated hardware as well as hardware capable of executing software in association with appropriate software. When provided by a processor, the functions may be provided by a single dedicated processor, by a single shared processor, or by a plurality of individual processors, some of which may be shared. In some embodiments of the present technology, the processor may be a general-purpose processor, such as a central processing unit (CPU) or a processor dedicated to a specific purpose, such as a digital signal processor (DSP). Moreover, explicit use of the term a “processor” should not be construed to refer exclusively to hardware capable of executing software, and may implicitly include, without limitation, application specific integrated circuit (ASIC), field programmable gate array (FPGA), read-only memory (ROM) for storing software, random access memory (RAM), and non-volatile storage. Other hardware, conventional and/or custom, may also be included.

Software modules, or simply modules which are implied to be software, may be represented herein as any combination of flowchart elements or other elements indicating performance of process steps and/or textual description. Such modules may be executed by hardware that is expressly or implicitly shown. Moreover, it should be understood that module may include for example, but without being limitative, computer program logic, computer program instructions, software, stack, firmware, hardware circuitry or a combination thereof which provides the required capabilities.

Given this fundamental understanding, the disclosed embodiments are directed to the control and balance of a datacenter liquid cooling system for rack-mounted processing assemblies. The control and balance of the liquid cooling system is based on maintaining an optimal differential temperature between supplied cooling liquid and returned heated liquid by dynamically adjusting the liquid flow rate for each individual rack-mounted processing assembly.

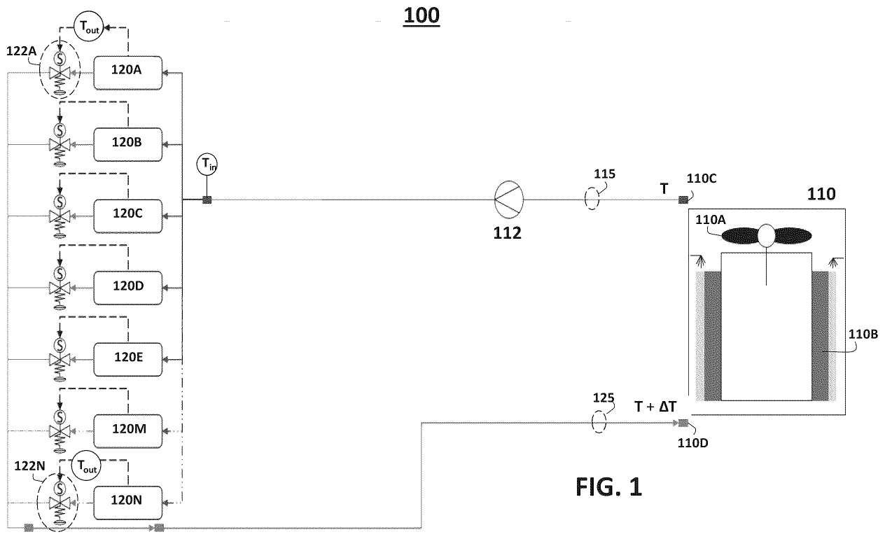

FIG. 1 illustrates the general architecture of a controlled and balanced liquid cooling system 100 for rack-mounted processing assemblies, in accordance with the non-limiting embodiments of the present technology. As shown, the system 100 includes a dry cooling unit 110, a plurality of rack-mounted processing assemblies 120A-120N, a plurality of “smart” valves 122A-122N in which each smart valve is fluidly-coupled to a respective processing assembly, a forward liquid distribution circuit 115 incorporating a pump 112 for supplying cooling liquid from the dry cooling unit 110, and a return liquid distribution circuit 125 for returning heated liquid back to the dry cooling unit 110.

The dry cooling unit 110 incorporates an outlet 110C configured to supply cooling liquid and an inlet 110D configured receive heated liquid. The dry cooling unit 110 serves to dissipate thermal energy from a heated liquid circulating therethrough to the ambient environment. For example, in a datacenter or similar facility, the dry cooling unit 110 operates to receive heated liquid from the rack-mounted processing assemblies 120A-120N (e.g., water circulated through water blocks in contact with heat-generating components) and extracts the thermal energy from the heated liquid by dissipating the energy into the ambient environment via the at least one fan assembly 110A, thereby re-cooling the heated liquid. The dry cooling unit 110 then operates to supply the re-cooled liquid back to the rack-mounted processing assemblies 120A-120N.

As shown, the dry cooling unit 110 includes at least one heat exchanger 110B and at least one fan assembly 110A. The heat exchanger 110 may manifest a variety of configurations, such as, air-to-liquid heat exchanger etc., and may further include evaporating or cooling pads. For purposes of the instant disclosure, the exact configuration of the dry cooling unit 110 and heat exchanger 110 is not limiting, as various configurations could be employed without departing from the concepts of the instant disclosure.

The cooling/re-cooled liquid is supplied by the dry cooling unit 110 to the rack-mounted processing assemblies 120A-120N via the outlet 110C and forward liquid distribution circuit 115. The forward liquid distribution circuit 115 incorporates a pump 112 to maintain the flow rate of the cooling/re-cooled liquid supplied to the processing assemblies 120A-120N at an adequate level.

The heated liquid from the rack-mounted processing assemblies 120A-120N is returned back to the dry cooling unit 110 for re-cooling via the inlet 110D and return liquid distribution circuit 125. As shown, the dry cooling unit 110 supplies the cooling/re-cooled liquid to the rack-mounted processing assemblies 120A-120N at a nominal temperature T and the heated liquid returned to the dry cooling unit 110 is at a nominal temperature T+ΔT, where ΔT represents the temperature differential between the cooling/re-cooled liquid and the heated liquid.

Returning to FIG. 1, the liquid cooling system 100 includes a plurality of rack-mounted processing assemblies 120A-120N which receive the supplied cooling/re-cooled liquid via the forward liquid distribution circuit 115, internally channel the liquid to the heat-generating processing components (e.g., water circulated through water blocks), and convey the heated liquid from the heat-generating processing components to the return liquid distribution circuit 125.

The rack-mounted processing assemblies 120A-120N may or may not be configured with similar heat-generating processing components. As such, each of the rack-mounted processing assemblies 120A-120N may have different temperature and flow rate requirements for proper operations.

It will be appreciated that, while the rack-mounted processing assemblies 120A-120N are shown to be arranged in a parallel configuration, it is not meant to be limiting, as the processing assemblies 120A-120N may also be arranged in a serial or combined parallel and serial configuration without departing from the concepts of the instant disclosure.

As shown, each of the rack-mounted processing assemblies 120A-120N is fluidly-coupled to a “smart” valve 122A-122N that dynamically controls the flow rate of the corresponding processing assembly 120A-120N based on detected liquid temperatures. For purposes of the instant disclosure, the term “smart” valve refers to a valve that is pressure-independent, temperature-responsive, and incorporates a differential pressure regulator to automatically adjust to system pressure changes. Such smart valves may comprise PICVs, ABQMs, or other functionally similar valves or combinations of valves, such as a solenoid valve combined with a control valve.

As shown, the temperature of the liquid ingressing into each of the rack-mounted processing assemblies 120A-120N is measured as Tᵢₙ which, depending on environmental factors and distances traversed, may or may not be the same as the temperature T of the cooling/re-cooled liquid supplied by the dry cooling unit 110.

The heated liquid egressing out of each of the rack-mounted processing assemblies 120A-120N is provided to the corresponding smart valve 122A-122N. Additionally, the temperature of the heated liquid egressing out of each processing assembly 120A-120N is measured as Tₒᵤₜ, which is also provided to the corresponding smart valve 122A-122N.

As will be described in detail below, based on the measured Tᵢₙ and Tₒᵤₜ of each of the processing assemblies 120A-120N, the corresponding smart valve 122A-122N functions to dynamically control the individual liquid flow rate of each of the rack-mounted processing assemblies to balance and maintain an optimal temperature differential ΔT between the supplied cooling/re-cooled liquid and the returned heated liquid of system 100. Maintaining this optimal temperature differential ΔT results in improved cooling system efficiency.

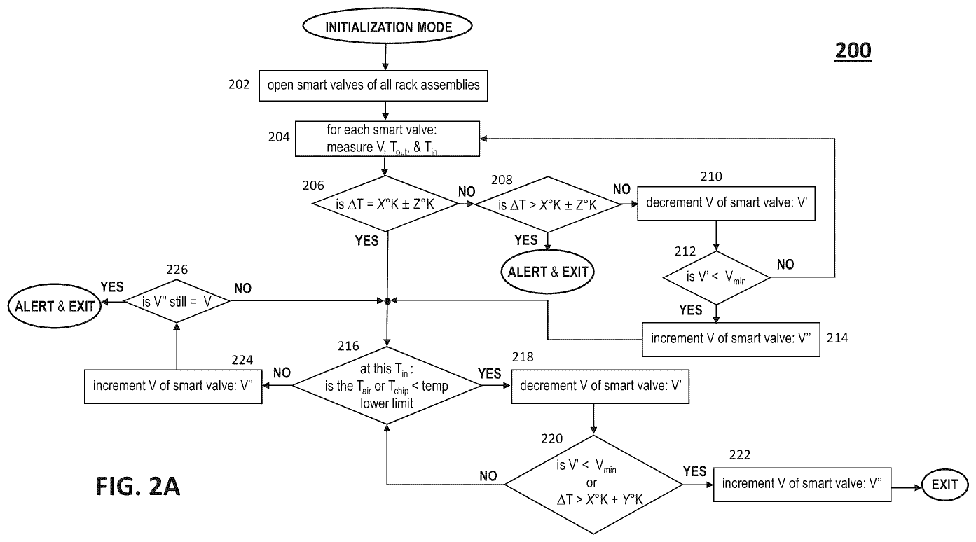

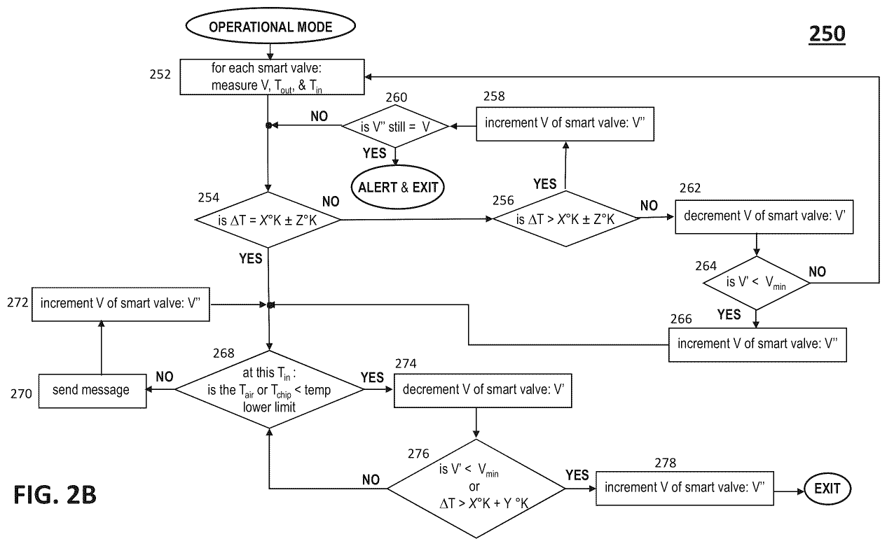

With this said, FIG. 2A illustrates a flow diagram of initialization process 200 for controlling and balancing a liquid cooling system for rack-mounted processing assemblies, in accordance with the non-limiting embodiments of the present technology. In some embodiments, initialization process 200 or portions thereof are to be executed by the individual rack-mounted processing assemblies that are respectively and directly connected to the smart valves 122A-122N. In other embodiments, initialization process 200 or portions thereof may be executed by a master control unit that is communicatively coupled to each of the individual rack-mounted processing assemblies. For purposes of the instant disclosure, the exact entity or entities executing initialization process is not limiting with regard to the concepts provided by the instant disclosure.

As such, initialization process 200 commences at task block 202, in which each of the of smart valves 122A-122N for all of the rack-mounted processing assemblies 120A-120N are opened. At task block 204, for each individual rack-mounted processing assembly 120A-120N, process 200 measures the liquid flow rate V of the rack-mounted assembly, the temperature of the heated liquid egressing out of the rack-mounted assembly Tₒᵤₜ, and the temperature of the cooling liquid ingressing into the rack-mounted assembly 120A-120N Tᵢₙ.

At decision block 206, process 200 determines whether the temperature differential ΔT between the ingressing cooling liquid and the egressing heated liquid is equal to a target temperature X° K within a tolerance value±Z° K. If not, at decision block 208, it is determined whether the temperature differential ΔT is greater than the tolerated target temperature X° K±Z° K and if it is, process 200 determines that the liquid flow rate V is insufficient and issues an alert message and exits the process. The tolerated target temperature X° K±Z° K is directly related to the optimal temperature differential ΔT that results in the improved cooling system efficiency.

However, if at decision block 208, it is determined that the temperature differential ΔT is not greater than the target temperature X° K±Z° K, then the liquid flow rate V is decremented by a predetermined value to V′ at task block 210. The predetermined decremental and incremental values may be based on a percentage of the total flow amount or on a quantified liter/min per kW amount. In turn, at decision block 212, it is determined whether the decremented liquid flow rate V′ is less than a predetermined minimum liquid flow rate Vₘᵢₙ and, if it is not, process 200 reverts back to task block 204 for the re-measuring of the liquid flow rate V′, the temperature of the heated liquid Tₒᵤₜ, and the temperature of the cooling liquid Tᵢₙ. If at decision block 212, it is determined that the decremented liquid flow rate V′ is less than the minimum liquid flow rate Vₘᵢₙ, the liquid flow rate V′ is then incremented by a predetermined value to V″ and directed to decision block 216 to be explained below.

Turning back to decision block 206, if it is determined that the temperature differential ΔT is equal to the tolerated target temperature X° K±Z° K, process 200 progresses to decision block 216 to determine whether, for the temperature of the cooling liquid Tᵢₙ, certain internal temperature metrics of the rack-mounted processing assemblies 120A-120N, such as, for example, air flow temperatures Tₐᵢᵣ and processing component temperatures T_{chips}, are less than a predetermined lower temperature limit, and if so, the liquid flow rate V is decremented by a predetermined value to V′ at task block 218.

Process 200 then progresses to decision block 220 to determine whether decremented liquid flow rate V′ is less than the predetermined minimum liquid flow rate Vₘᵢₙ or whether the temperature differential AT is greater than the tolerated target X° K±Z° K in addition to an acceptable offset temperature Y° K. If any one of these conditions are met, process 200 moves to task block 222 to increment the liquid flow rate V by a predetermined value to V″ and then exit process 200.

If none of the conditions of decision block 220 are met, process 200 returns back to decision block 216 which again determines if for the temperature Tᵢₙ, certain internal temperature metrics of the rack-mounted processing assemblies 120A-120N, such as, Tₐᵢᵣ and T_{chips} are less than a predetermined lower temperature limit, and if so, process 200 cycles back through blocks 218, 220, and 222. However, if none of the conditions of decision block 216 are met, process 200 advances to block 224 to increment the liquid flow rate V by a predetermined value to V″ and moves to decision block 226.

At decision block 226, it is determined whether the incremented flow rate V″ is the same as liquid flow rate V, and if so, process 200 determines that the liquid flow rate V″ is insufficient and issues an alert message and exits the process. However, if incremented flow rate V″ is not the same as liquid flow rate V, process 200 cycles back to decision block 216.

In this manner, process 200 initializes system 100 to calibrate each of the smart valves 122A-122N corresponding to each of the rack-mounted processing assemblies 120A-120N in order to balance liquid flow rates and temperatures to maintain an optimal temperature differential ΔT between the supplied cooling/re-cooled liquid and the returned heated liquid for maximum cooling efficiency.

FIG. 2B illustrates a flow diagram of operational process 250 for controlling and balancing a liquid cooling system for rack-mounted processing assemblies, in accordance with the nonlimiting embodiments of the present technology. In some embodiments, operational process 250 or portions thereof are to be executed by the individual rack-mounted processing assemblies that are respectively and directly connected to the smart valves 122A-122N. In other embodiments, operational process 250 or portions thereof may be executed by a master control unit that is communicatively coupled to each of the individual rack-mounted processing assemblies. For purposes of the instant disclosure, the exact entity or entities executing initialization process is not limiting with regard to the concepts provided by the instant disclosure.

Operational process 250 commences at task block 252, in which for each individual rack-mounted processing assembly 120A-120N, the liquid flow rate V of the rack-mounted assembly, the temperature of the heated liquid egressing out of the rack-mounted assembly Tₒᵤₜ, and the temperature of the cooling liquid ingressing into the rack-mounted assembly 120A-120N Tᵢₙ are measured.

Process 250 then moves to decision block 254, where it is determined whether the temperature differential ΔT between the ingressing cooling liquid and the egressing heated liquid is equal to a target temperature X° K within a tolerance value±Z° K. If not, decision block 256 determines whether the temperature differential ΔT is greater than the tolerated target temperature X° K±Z° K and if it is, the liquid flow rate V is incremented by a predetermined value to V″. Then, decision block 260 determines whether incremented flow rate V″ is the same as liquid flow rate V, and if so, process 250 determines that the liquid flow rate V″ is insufficient and issues an alert message and exits the process. However, if V″ is not the same as liquid flow rate V, process 250 returns back to decision block 254.

Returning back to decision block 256, if it is determined that the temperature differential ΔT is not greater than the tolerated target temperature X° K±Z° K, process 250 decrements the liquid flow rate V by a predetermined value to V′ at task block 262 and then, at decision block 264, determines whether the decremented liquid flow rate V′ is less than a predetermined minimum liquid flow rate Vₘᵢₙ. The predetermined minimum liquid flow rate Vₘᵢₙ is configured to prevent laminar flows within the internally channelized liquid circulated within water blocks, limit the accumulated deposition of debris or minerals within the water blocks, and/or prevent overheating within the channels.

If decision block 264 determines that V′ is not less than Vₘᵢₙ, process 250 returns back to task block 252 for the remeasuring of V, Tᵢₙ, and Tₒᵤₜ of the rack-mounted assembly. If decision block 264 determines that V′ is less than Vₘᵢₙ, process 250 advances to task block 266 to increment the liquid flow rate V by the predetermined value to V″.

Returning back to decision block 254, if it is determined that the temperature differential ΔT is equal to a target temperature X° K within a tolerance value±Z° K, process 250 advances to decision block 268 to determine whether, for the temperature of the cooling liquid Tin, certain internal temperature metrics of the rack-mounted processing assemblies 120A-120N, such as, for example, air flow temperatures Tₐᵢᵣ and processing component temperatures T_{chips}, are less than a predetermined lower temperature limit. If the Tₐᵢᵣ and T_{chips} temperatures are not, at task 270, process 250 issues a precautionary message indicating the potential of high temperatures within the rack-mounted processing assemblies 120A-120N. Then, at task block 272, the liquid flow rate V is incremented by the predetermined value to V″.

On the other hand, if decision block 268 determines that the air flow temperatures Tₐᵢᵣ and processing component temperatures T_{chips} are less than the predetermined lower temperature limit, process 250 advances to task block 274 to decrement the liquid flow rate V by a predetermined value to V′. Then, decision block 276 determines whether the decremented liquid flow rate V′ is less than the predetermined minimum liquid flow rate Vₘᵢₙ or whether the temperature differential ΔT is greater than the tolerated target temperature tolerated target temperature X° K±Z° K in addition to an acceptable offset temperature Y° K. If none of these conditions are met, process 250 cycles back to decision block 268. However, if any of these conditions are met, process 250 moves to task 278 to increment the liquid flow rate V by the predetermined value to V″ and then exits the process.

In this manner, process 250 functions to control and balance the liquid flow rates of provided by each of the smart valves 122A-122N corresponding to each of the rack-mounted processing assemblies 120A-120N during operations, in order to maintain an optimal temperature differential ΔT between the supplied cooling/re-cooled liquid and the returned heated liquid for maximum cooling efficiency.

While the above-described implementations have been described and shown with reference to particular steps performed in a particular order, it will be understood that these steps may be combined, sub-divided, or re-ordered without departing from the teachings of the present technology. At least some of the steps may be executed in parallel or in series. Accordingly, the order and grouping of the steps is not a limitation of the present technology.

Modifications and improvements to the above-described implementations of the present technology may become apparent to those skilled in the art. The foregoing description is intended to be exemplary rather than limiting. The scope of the present technology is therefore intended to be limited solely by the scope of the appended claims.

What is claimed is:

1. A liquid cooling method for rack-mounted processing assemblies, comprising:
providing a dry cooling unit to supply a cooling liquid to the rack-mounted processing assemblies and receive a heated liquid from the rack-mounted processing assemblies;
providing a first liquid distribution circuit to convey the cooling liquid from the dry cooling unit to the rack-mounted processing assemblies and a second liquid distribution circuit to convey the heated liquid from the rack-mounted processing assemblies to the dry cooling unit;
wherein, each of the rack-mounted data processing assemblies comprises:
at least one heat-generating electronic processing element and at least one liquid cooling block arranged to be in respective thermal contact with the at least one heat-generating electronic processing element, the at least one liquid cooling block being fluidly-coupled to the first liquid distribution circuit to receive the cooling liquid and circulate therethrough, and
a smart control valve respectively arranged to be fluidly-coupled to the at least one liquid cooling block of the corresponding rack-mounted data processing assembly, the smart control valve is configured to be pressure independent and controls the flow rate of the cooling fluid of the corresponding rack-mounted data processing assembly based on detected temperatures and pressure flows;
wherein, each smart control valve operates to execute an initialization process, comprising:
measuring the liquid flow rate, input cooling liquid temperature, and output heated liquid temperature of the corresponding rack-mounted data processing assembly, and calculating a differential temperature between the input cooling liquid temperature and output heated liquid temperature,
determining a relationship between the differential temperature and a target temperature value, and
initializing the liquid flow rate of the smart control valve based on the determined relationship prior to operations; and
wherein, each smart control valve operates to execute an operational process, comprising:
measuring a current liquid flow rate, current input cooling liquid temperature, and current output heated liquid temperature of the corresponding rack-mounted data processing assembly, and calculating a current differential temperature between the current input cooling liquid temperature and current output heated liquid temperature,
determining a relationship between the current differential temperature and a target temperature value, and
dynamically adjusting the liquid flow rate of the smart control valve based on the determined relationship and the current liquid flow rate and current input cooling liquid temperature.

2. The liquid cooling method of claim 1, wherein the initialization process further comprises that, when the differential temperature is greater than the target temperature value, issuing an alert message indicating that the liquid flow rate of the corresponding smart control valve is insufficient.

3. The liquid cooling method of claim 1, wherein the initialization process further comprises that, when the differential temperature is less than the target temperature value, decrementing the liquid flow rate of the corresponding smart control valve after confirming that the decremented flow rate is not below a minimum flow rate limit.

4. The liquid cooling method of claim 1, wherein the initialization process further comprises that, when the differential temperature is equal to the target temperature value, determining whether at the input cooling liquid temperature, internal temperatures of the rack-mounted processing assembly are less than a predetermined lower temperature limit, and
when the internal temperatures are less than the predetermined lower temperature limit, decrementing the liquid flow rate of the corresponding smart control valve, and
when the internal temperatures are greater than the predetermined lower temperature limit, incrementing the liquid flow rate of the corresponding smart control valve.

5. The liquid cooling method of claim 1, wherein the operational process further comprises that, when the current differential temperature is greater than the target temperature value, incrementing the liquid flow rate of the corresponding smart control valve.

6. The liquid cooling method of claim 5, wherein the operational process further comprises that, when the incremented liquid flow rate is the same as the current flow rate, issuing an alert message indicating that the liquid flow rate of the corresponding smart control valve is insufficient.

7. The liquid cooling method of claim 5, wherein the operational process further comprises that, when the current differential temperature is less than the target temperature value, decrementing the liquid flow rate of the corresponding smart control valve after confirming that the decremented flow rate is not below a minimum flow rate limit.

8. The liquid cooling method of claim 5, wherein the operational process further comprises that, when the current differential temperature is equal to the target temperature value, determining whether at the current input cooling liquid temperature, internal temperatures of the rack-mounted processing assembly are less than a predetermined lower temperature limit, and
when the internal temperatures are less than the predetermined lower temperature limit, decrementing the liquid flow rate of the corresponding smart control valve, and then checking whether the decremented flow rate is below a minimum flow rate limit or the current differential temperature is greater than the target temperature plus an offset temperature.

9. The liquid cooling method of claim 8, wherein the operational process further comprises that, when the decremented flow rate is below a minimum flow rate limit or the current differential temperature is greater than the target temperature plus an offset temperature, incrementing the current liquid flow rate of the corresponding smart control valve.

10. The liquid cooling method of claim 8, wherein the operational process further comprises that, for the current input cooling liquid temperature, when the internal temperatures of the rack-mounted processing assembly are greater than a predetermined lower temperature limit, issuing a message indicating a precautionary message indicating a potential trend of high temperatures and incrementing the incrementing the current liquid flow rate of the corresponding smart control valve.

11. A liquid cooling system for rack-mounted processing assemblies, comprising:
a dry cooling unit configured to supply a cooling liquid to the rack-mounted processing assemblies and receive a heated liquid from the rack-mounted processing assemblies;
a first liquid distribution circuit configured to convey the cooling liquid from the dry cooling unit to the rack-mounted processing assemblies, the first liquid distribution circuit incorporating a pump configured to drive a flow of the cooling liquid supplied by the dry cooling unit;
a second liquid distribution circuit configured to convey the heated liquid from the rack-mounted processing assemblies to the dry cooling unit;
wherein, each of the rack-mounted data processing assemblies comprises:
at least one heat-generating electronic processing element,
at least one liquid cooling block arranged to be in respective thermal contact with the at least one heat-generating electronic processing element, the at least one liquid cooling block being fluidly-coupled to the first liquid distribution circuit to receive the cooling liquid and circulate therethrough, and
a smart control valve respectively arranged to be fluidly-coupled to the at least one liquid cooling block of the corresponding rack-mounted data processing assembly, the smart control valve is configured to be pressure independent and controls the flow rate of the cooling fluid of the corresponding rack-mounted data processing assembly based on detected temperatures and pressure flows;
wherein, in an initialization mode, each smart control valve operates to:
measure the liquid flow rate, input cooling liquid temperature, and output heated liquid temperature of the corresponding rack-mounted data processing assembly, and
calculate a differential temperature between the input cooling liquid temperature and output heated liquid temperature,
determine a relationship between the differential temperature and a target temperature value, and
initialize the liquid flow rate of the smart control valve based on the determined relationship prior to an operational mode; and
wherein, in the operational mode, each smart control valve operates to:
measure a current liquid flow rate, current input cooling liquid temperature, and current output heated liquid temperature of the corresponding rack-mounted data processing assembly, and calculate a differential temperature between the current input cooling liquid temperature and current output heated liquid temperature,
determine a relationship between the differential temperature and a target temperature value, and
dynamically adjust the liquid flow rate of the smart control valve based on the determined relationship and the measured current liquid flow rate and current input cooling liquid temperature.

12. The liquid cooling system of claim 11, wherein the initialization process further comprises that, when the differential temperature is greater than the target temperature value, issuing an alert message indicating that the liquid flow rate of the corresponding smart control valve is insufficient and when the differential temperature is less than the target temperature value, decrementing the liquid flow rate of the corresponding smart control valve after confirming that the decremented flow rate is not below a minimum flow rate limit.

13. The liquid cooling system of claim 11, wherein the initialization process further comprises that, when the differential temperature is equal to the target temperature value, determining whether at the input cooling liquid temperature, internal temperatures of the rack-mounted processing assembly are less than a predetermined lower temperature limit, and
when the internal temperatures are less than the predetermined lower temperature limit, decrementing the liquid flow rate of the corresponding smart control valve, and
when the internal temperatures are greater than the predetermined lower temperature limit, incrementing the liquid flow rate of the corresponding smart control valve.

14. The liquid cooling system of claim 11, wherein the operational process further comprises that:
when the current differential temperature is greater than the target temperature value, incrementing the liquid flow rate of the corresponding smart control valve and if the incremented liquid flow rate is the same as the current flow rate, issuing an alert message indicating that the liquid flow rate of the corresponding smart control valve is insufficient;
when the current differential temperature is equal to the target temperature value, determining whether at the current input cooling liquid temperature, internal temperatures of the rack-mounted processing assembly are less than a predetermined lower temperature limit; and
when the internal temperatures are less than the predetermined lower temperature limit, decrementing the liquid flow rate of the corresponding smart control valve, and then checking whether the decremented flow rate is below a minimum flow rate limit or the current differential temperature is greater than the target temperature plus an offset temperature.

15. The liquid cooling system of claim 14, wherein the operational process further comprises that, for the current input cooling liquid temperature, when the internal temperatures of the rack-mounted processing assembly are greater than a predetermined lower temperature limit, issuing a message indicating a precautionary message indicating a potential trend of high temperatures and incrementing the incrementing the current liquid flow rate of the corresponding smart control valve.
